(19) United States
(12) Patent Application Publication
(10) Pub. No.: US 2025/0206672 A1
(43) Pub. Date: Jun. 26, 2025

(54) 3D-PRINTABLE PIEZOELECTRIC CERAMIC COMPOSITIONS WITH CARBON NANOMATERIALS

(71) Applicants: National Research Council of Canada, Ottawa (CA); Xerox Corporation, Norwalk, CT (US)

(72) Inventors: Yujie ZHANG, Ottawa (CA); Thomas LACELLE, Ottawa (CA); Mohammad RAFIEE, Ottawa (CA); Chantal PAQUET, Ottawa (CA); Derek ARANGUREN VAN EGMOND, Ottawa (CA); Silvio Elton KRUGER, Brossard (CA); Claudie ROY, Montreal (CA); Sarah VELLA, Milton (CA); Ekaterina KOMAROVA, Toronto (CA)

(21) Appl. No.: 18/848,977

(22) PCT Filed: Mar. 16, 2023
(86) PCT No.: PCT/CA2023/050337

§ 371 Date: Sep. 20, 2024

Related U.S. Application Data
(60) Provisional application No. 63/322,329, filed on Mar. 22, 2022.

(51) Int. Cl. C04B 35/491; B33Y 70/00; C04B 35/78

(52) U.S. Cl. CPC C04B 35/491; B33Y 70/00; C04B 35/78; C04B 2235/422

(57) ABSTRACT

An extrudable ceramic composition comprises piezoelectric ceramic particles and carbon nanomaterial particles suspended in a carrier medium. A piezoelectric ceramic material is produced by curing the composition. The carbon nanomaterials are used as additives to extrudable ceramic compositions (e.g., piezoelectric compositions such as PZT/polymer composites, PZT/sol-gel composites, PZT emulsion pastes and the like). The addition of carbon nanomaterials imparts both beneficial rheological properties (shear thinning) and improved piezoelectric performance to the ceramic material.

### CROSS-REFERENCE TO RELATED APPLICATIONS

This application claims the benefit of U.S. Provisional Application 63/322,329 filed Mar. 22, 2022, the entire contents of which is herein incorporated by reference.

### FIELD

This application relates to piezoelectric ceramic compositions, methods of producing piezoelectric ceramic compositions and their use, particular in piezoelectric sensors and actuators.

### BACKGROUND

Piezoelectric materials have the ability to convert electrical energy to mechanical energy when generating an interrogating acoustic pulse, and conversely, they can convert mechanical energy into electrical energy while detecting the echoes of an acoustic pulse. These materials are used for a wide range of technological applications that include ultrasound transducers for naval, medical and nondestructive evaluation applications, fuel injectors for diesel engines and cantilevers for harvesting energy from ambient vibrations. The versatility of piezoelectric materials has found widespread applications as sensors, actuators, transducers, and energy harvesters in industries including aerospace, automotive, mining, nuclear, oil and gas, manufacturing, and biomedical.

Sol-gel processes to fabricate piezoelectric films have been used to fabricate outstanding ultrasonic transducers used to monitor cracks, corrosion, and erosion. Their superior performance combined with low footprint and flexibility make these transducers of high interest. However, there is an emerging need to manufacture high volumes of embedded sensors to obtain more accurate sensing data. Production methodology of lead zirconate titanate (PZT) ceramics currently used, which entails numerous material layers, is labor and time intensive with low freedom to modify design parameters. Commercial products that provide manufacturing solutions, such as those based on PVDF polymers, do not meet the performance requirements needed for most sensing applications. Therefore, there is a need for ceramic-based materials that are compatible with additive processes, allowing increased design freedom and ease of integration into parts.

3D printing methods, such as extrusion and direct ink writing, are well-suited to transition lengthy sol-gel material assembly into an industry-relevant process. 3D printing via direct ink writing (DIW) is an approach that offers the possibility to design and create objects in a variety of shapes and sizes by simple extrusion of paste-like materials (inks) through a nozzle, whereby the object's structure can be controlled by the deposition pattern of the filaments. This approach has been used to fabricate piezoelectric materials using piezoelectric inks made of a mixture of piezoceramic particles and a polymer matrix.

Successful printing of piezoelectric materials using DIW imposes stringent requirements on the rheological properties of the paste. Often, optimizing the rheological properties of the paste for DIW occurs at the expense of the performance of the piezoelectric material once printed. That is, DIW pastes must easily flow through a narrow opening, but they must also resist deformation immediately after printing. Depending on the loading of piezoelectric materials in the pastes, the viscosity of the paste may need some adjustments, which is often done by adding rheology modifying polymers or diluting the amount of functional material (i.e., the ceramic particles), both of which will negatively affect the effective piezoelectric properties (e.g., d₃₃ value) of the fabricated samples. In addition, without properly formulating piezoceramic/polymer composites, the agglomeration of piezoelectric particles may create a discontinuous phase of piezoelectric particles and polymer matrix. This may lead to a significant drop in the piezoelectric properties (i.e., lower d₃₃) of the fabricated parts.

There remains a need for ceramic compositions that are printable and that provide improved piezoelectric properties together with desired rheological, physical and mechanical properties.

### SUMMARY

An extrudable ceramic composition comprises piezoelectric ceramic particles and carbon nanomaterial particles suspended in a carrier medium.

A piezoelectric ceramic material produced by curing the composition described above.

The carbon nanomaterials are used as additives to extrudable ceramic compositions (e.g., piezoelectric pastes such as PZT/polymer composites, PZT/sol-gel composites, PZT emulsion pastes and the like). The addition of carbon nanomaterials imparts both beneficial rheological properties (shear thinning) and improved piezoelectric performance. The benefits and improvement can be realized by simply mixing desired amounts and types of carbon nanomaterials with any existing piezoelectric ceramic compositions. Depending on the concentrations and types of carbon nanomaterials chosen, one can finely tune the piezoelectric properties, poling efficiency, mechanical properties, rheological properties and many other properties accordingly.

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

For clearer understanding, preferred embodiments will now be described in detail by way of example, with reference to the accompanying drawings, in which:

FIG. 1 depicts a graph of d₃₃ (pC/N) vs. graphene oxide (GO) concentration (wt %) in a lead zirconate titanate (PZT) emulsion paste.

FIG. 2 depicts a graph of d₃₃ (pC/N) vs. graphene oxide (GO) concentration (wt %) in an annealed lead zirconate titanate (PZT) sol-gel paste containing 80 wt % PZT.

FIG. 3 depicts scanning electron micrograph (SEM) images of the PZT emulsion paste containing NOA 89H organic polymer material.

### DETAILED DESCRIPTION

The compositions of the present invention comprise carbon nanomaterials no matter which type of ceramic composition formulations is utilized. Carbon nanomaterials include, for example, graphite, graphene, graphene oxide (GO), reduced graphene oxide (r-GO), carbon nanotubes (e.g., single-walled carbon nanotubes, multi-walled carbon nanotubes), fullerenes, carbon nanofibers and the like and any mixture thereof. Carbon nanomaterial particles are preferably present in the paste in an amount in a range of 0.01-2 wt % based on total weight of the composition, more preferably 0.05-1 wt %

Any type of ceramic composition formulation can be used. Some examples include ceramic/polymer composites, ceramic/sol-gel composites and ceramic emulsion pastes. Suitable ceramic/polymer composites and ceramic/sol-gel composites are described in International Patent Application PCT/CA2021/051173 filed Aug. 24, 2021, the entire contents of which is herein incorporated by reference. The types of ceramic composition formulations are distinguished from each other by the nature of the carrier medium.

All of the types of ceramic composition formulations comprise ceramic particles. The ceramic particles may be made of lead zirconate titanate (PZT) or other ceramic materials such as those with perovskite structures which include BaTiO₃, KNbO₃, ZnO, BiFO₃ and Bi₄Ti₃O₁₂. A combination of these may be used. The ceramic particles are preferably present in the paste in an amount in a range of 90 wt % or less, based on the total weight of the composition. In some embodiments, the ceramic particles are present in an amount of 70 wt % or less, or 65 wt % or less. The ceramic particles may be present in the paste in an amount in a range of 35-90 wt %, or 35-80 wt %. The ceramic particles preferably have an average particle diameter of 100 nm or greater, more preferably 500 nm or greater. The ceramic particles preferably have an average particle diameter of 40 μm or less, more preferably 10 μm or less. The ceramic particles are preferably crystalline.

Ceramic/polymer composites do comprise an organic polymer binder, while ceramic/sol-gel composites and ceramic emulsion pastes may comprise an organic polymer binder. The organic polymer binder is a component of the carrier medium for the paste. The organic polymer binder is preferably water-soluble, especially for aqueous ceramic/sol-gel composites and ceramic emulsion pastes. Water-soluble organic polymer binders include, for example, polyvinylpyrrolidone (PVP), polyacrylic acid (PAA), polyvinyl alcohol (PVA), polyethyleneglycol (PEG) or any combination thereof. The paste preferably comprises 0.05-5 wt %, more preferably 2-5 wt %, of the water-soluble organic polymer binder, based on the total weight of the composition. In addition to being a binder, the polymer can act as a rheology modifier and/or a stabilizer. The water-soluble organic polymer binder is particularly useful for the tuning of the rheological properties of the paste to ensure that the paste forms a uniform suspension and is capable of being deposited while also being able to support itself during printing. Further, the water-soluble organic polymer binder also serves to minimize cracks, delamination between printed layers and allows a high loading of the ceramic particles in the paste.

Ceramic/sol-gel composites do comprise a sol-gel of ceramic precursors, while ceramic emulsion pastes may comprise a sol-gel of ceramic precursors. The sol-gel is a component of the carrier medium for the paste. The sol-gel is preferably an aqueous sol-gel. Sol-gels may be initially prepared by using standard acid-catalyzed aqueous based sol-gel synthesis techniques. The sol-gel preferably comprises ceramic nanoparticles, especially lead zirconate titanate (PZT), BaTiO₃, KNbO₃, ZnO, BiFO₃, Bi₄Ti₃O₁₂ or any combination thereof, suspended in a gel. The ceramic particles are generally formed during the preparation of the sol-gel from ceramic precursors, for example by a reaction between a metal salt and a suitable oxide. For example, BaTiO₃ particles can be formed through the reaction of barium acetate and titanium (IV) isopropoxide during gelation of the sol-gel. The ceramic particles formed in this way are generally amorphous and have an average particle diameter of under 100 nm. The sol-gel is preferably present in the paste in an amount of 1-10 wt %, based on total weight of the composition, more preferably 2-7 wt %. The sol-gels are made from ceramic precursors, which provides a stiff material matrix helping to increase the piezoelectric response of the material. Sol-gel nanoparticles are particularly useful for the tuning of the rheological properties of the paste to ensure that the paste forms a uniform suspension and is capable of being deposited while also being able to support itself during printing.

Ceramic/sol-gel composites may comprise a high boiling solvent instead of or in addition to an organic polymer binder. The high boiling solvent is a component of the carrier medium for the paste. High boiling point solvents are liquids having a boiling point of at least 100° C. at a pressure of 760 mmHg. Preferably, the boiling point is in a range of from 100° C. to 280° C. or from 100° C. to 250° C., more preferably 110° C. to 280° C. or 110° C. to 250° C. The high boiling point solvent preferably comprises an organic solvent or a mixture thereof. The high boiling point solvent preferably comprises an alcohol or mixtures of one or more alcohols with at least one other solvent. Some preferred solvents include 1-butanol, 2-methyl-2-propanol, 1-pentanol, 3-methyl-1-butanol, 2,2-dimethyl-1-propanol, cyclopentanol, 1-hexanol, cyclohexanol, 1-heptanol, 1-octanol, propylene carbonate, tetraglyme, 2-(2-methoxyethoxy)acetic acid or any mixture thereof. Where one of the solvents alone has a boiling point of less than 100° C., the presence of other solvents can raise the boiling temperature of the high boiling point solvent to 100° C. or higher. The high boiling point solvent is preferably present in the paste in an amount of 3.5-35 wt. %, based on total weight of the composition, preferably 5-35 wt. %. In some embodiments, the amount of high boiling solvent is preferably 3.5-12 wt. % or 3.5-7.5 wt. % or 3.5-5 wt. % or 3.7-4.5 wt. %. Especially when the high boiling point solvent has a boiling point over 100° C., the high boiling point solvent reduces clogging of a printing nozzle by the paste formulation ensuring more consistent printing and extending the shelf-life of the paste in comparison to lower boiling point solvents that tend to readily evaporate over time and during the printing step.

Ceramic emulsion pastes comprise: an aqueous phase comprising acidic water and ceramic particles suspended in the water; and, an organic phase comprising an organic solvent, a curable polymer precursor or both an organic solvent and a curable polymer precursor. The acidic water, organic solvent and curable polymer precursor are components of the carrier medium for the paste. The aqueous phase of a ceramic emulsion paste comprises water. The water is acidic having a pH of less than 7. Preferably, the pH is in a range of 2-5. The water is preferably present in the paste in an amount in a range of 5-25 wt %, based on total weight of the composition, more preferably 7-20 wt %, yet more preferably 7-17 wt %. The aqueous phase also comprises the ceramic particles, which may be suspended or otherwise dispersed in the water. Suitable ceramic particles are described above. The aqueous phase may also contain the water-soluble organic polymer binder if a water-soluble organic polymer binder is used. Suitable water-soluble organic polymer binders are described above.

The aqueous phase of a ceramic emulsion paste may further comprise a surfactant. The surfactant is preferably an anionic surfactant that stabilizes cationic metal ions in an aqueous environment. Anionic surfactants contain anionic functional groups, such as sulfate, sulfonate, phosphate and carboxylates. Some examples include alkyl sulfates include ammonium lauryl sulfate, sodium lauryl sulfate (sodium dodecyl sulfate, SLS, or SDS), and the related alkyl-ether sulfates sodium laureth sulfate (sodium lauryl ether sulfate or SLES), and sodium myreth sulfate. The Tween™ series surfactants are particularly preferred, such as polysorbate 20 (polyoxyethylene (20) sorbitan monolaurate), polysorbate 40 (polyoxyethylene (20) sorbitan monopalmitate), polysorbate 60 (polyoxyethylene (20) sorbitan monostearate), polysorbate 80 (polyoxyethylene (20) sorbitan monooleate). The surfactant is preferably present in the paste in an amount in a range of 0.1-2 wt % based on total weight of the composition, more preferably 0.5-1 wt %.

The organic phase of a ceramic emulsion paste comprises an organic solvent or a curable polymer precursor. In some embodiments, the organic phase comprises an organic solvent. The organic solvent should be sufficiently hydrophobic to form separate phase from the aqueous phase. The organic solvent may comprise a mixture of different organic solvents. Some examples of organic solvents include liquid alkanes (e.g., pentanes, hexanes, heptanes, octanes, nonanes, decanes, undecanes, dodecanes and the like). Alkanes are preferred, especially octane. The organic solvent is preferably present in the paste in an amount in a range of 15-55 wt % based on total weight of the composition, more preferably 20-50 wt %. The organic solvent is sacrificial. Once the emulsion is printed, the organic solvent is allowed to evaporate thereby forming a porous ceramic structure. Thus, post printing and processing, the print is a porous ceramic structure. The porous ceramic structure is then infiltrated with an organic polymeric material to fill the pores to produce a ceramic material with a co-continuous phase, preferably a bicontinuous phase.

In some embodiments, the organic phase comprises a curable polymer precursor. The curable polymer precursor may be one or more monomers or a resin. The curable polymer precursor is curable to produce an organic polymeric material. Curing may be performed by any suitable method, for example thermal or photonic curing, in the presence or absence of an initiator depending on the polymer precursors involved. The curable polymer precursor preferably comprises acrylates (e.g., 2-ethylhexyl acrylate (EHA), 1,6-hexanediol diacrylate (HAD)), methacrylate-based resins, urethanes, mercapto ester-based polymers, ethers (e.g., 4-butanediol divinyl ether (BDE)), pentaerythritols (e.g., pentaerythritol tetra (3-mercaptopropionate) (PETMP), styrenes, vinylics, epoxy-based resins, thiol-based resins, or mixtures thereof. A particularly useful class of curable polymer precursors are thiol-ene systems comprising thiol and vinyl precursors, preferably containing an initiator to permit thermal curing. Thiol-ene systems may comprise mixtures of dithiols, trithiols or tetrathiols with divinyls, trivinyls or tetravinyls. Other systems include, for example, mixtures of dithiols, trithiols or tetrathiols with diacrylates, triacrylates or tetraacrylates; or, mixtures of dithiols, trithiols or tetrathiols with dimethacrylates, trimethacrylates or tetramethacrylates.

Some specific examples of curable polymer precursors are ethyleneglycol methyl ether acrylate, N,N-diisobutyl-acrylamide, N-vinyl-pyrrolidone, (meth)acryloyl morpholine, 7-amino-3,7-dimethyloctyl, (meth) acrylate, isobutoxymethyl (meth) acrylamide, isobornyloxyethyl (meth)acrylate, isobornyl (meth)acrylate, 2-ethylhexyl acrylate, 2-ethylhexyl (meth)acrylate, ethyldiethylene glycol (meth)acrylate, t-octyl (meth)acrylamide, diacetone (meth) acrylamide, dimethylaminoethyl (meth)acrylate, diethylaminoethyl (meth) acrylate, lauryl (meth) acrylate, dicyclopentadiene (meth)acrylate, dicyclopentenyloxyethyl (meth) acrylate, dicyclopentenyl (meth) acrylate, N,N-dimethyl (meth) acrylamide tetrachlorophenyl (meth)acrylate, 2-tetrachlorophenoxyethyl (meth)acrylate, tetrahydrofurfuryl (meth)acrylate, tetrabromophenyl (meth)acrylate, 2-tetrabromophenoxyethyl (meth) acrylate, 2-trichlorophenoxyethyl (meth)acrylate, tribromophenyl(meth)acrylate, 2-tribromophenoxyethyl (meth) acrylate, 2-hydroxyethyl (meth)acrylate, 2-hydroxypropyl (meth)acrylate, vinyl caprolactam, phenoxyethyl (meth)acrylate, butoxyethyl (meth)acrylate, pentachlorophenyl (meth)acrylate, pentabromophenyl (meth)acrylate, polyethylene glycol mono-(meth)acrylate, methyl triethylene diglycol (meth)acrylate, alkoxylated alkyl phenol acrylate, (poly)caprolactone acrylate ester from methylol-tetrahydrofuran, (poly)caprolactone acrylate ester from alkylol-dioxane, ethylene glycol phenyl ether acrylate, methacryloxypropyl terminated polydimethylsiloxane, or any mixture thereof.

The curable polymer precursor is preferably present in the composition in an amount in a range of 15-55 wt % based on total weight of the composition, more preferably 15-40 wt %. After printing the emulsion and drying the printed emulsion to remove the water, thermally or photonically treating the dried emulsion initiates curing of the curable polymer precursor to form an organic polymeric material thereby producing a ceramic material with a co-continuous phase.

The composition preferably has a form factor suitable for additive manufacturing. Suitable form factors of the compositions that may be processed by extrusion include composite filaments, composite pellets, composite powders, composite pastes, or any combination thereof.

Composite filaments compatible with fused filament fabrication may be formed. Although composite filaments may be an advantageous and particularly versatile form factor, it is to be realized that composite pellets may also be produced by producing larger extrudates, which may then be cut, shredded, pulverized, or the like to afford composite pellets of a specified size and geometry or composite powders having even smaller dimensions and a wide distribution of particle sizes. Other than having a different shape, the microscopic morphology of the composite pellets may be similar to that of composite filaments. Like composite filaments, composite pellets and composite powders may be subsequently processed into printed parts having piezoelectric properties under suitable additive manufacturing conditions. “Filaments” are to be distinguished from “fibers” on the basis that filaments comprise a single elongate form factor, whereas fibers comprise multiple filaments twisted together (bundled) to form a fine thread or wire in which the individual filaments remain identifiable. As such, filaments have smaller diameters than do fiber bundles formed therefrom, assuming no filament compression takes place when forming a fiber bundle. Filaments obtained by solution electrospinning or melt electrospinning are usually up to about 100 μm in diameter, which is too small to be effectively printed using fused filament fabrication. The composite filaments obtained herein, in contrast, may be about 0.5 mm or more in size and dimensioned for compatibility with a particular printing system for fused filament fabrication.

Extrudable composite pastes are particularly preferred. As used herein, the term “paste” refers to a composition that is at least partially fluid at a temperature of interest. The term “paste” does not necessarily imply an adhesive function of any type. Moreover, the terms “paste” and “ink” may be used interchangeably with one another in the disclosure herein with respect to direct writing additive manufacturing processes. Unlike composite filaments and composite pellets discussed in brief above, extrudable composite pastes may comprise at least one solvent to facilitate extrusion. The piezoelectric ceramic particles may be suspended in an aqueous phase whereby the paste is an emulsion of the aqueous phase and an organic phase. The organic phase may comprise an organic solvent and/or curable polymer precursors, whereby a co-continuous morphology occurs upon formulation or printing of the extrudable composite paste.

Pastes may be deposited by any suitable method, for example 2-D printing (e.g., screen printing), 3-D printing (e.g., material extrusion or direct-ink-writing (DIW)), stereolithography, powder fusion, vat photopolymerization, binder bonding and the like. The paste is best suited for 3-D printing. DIW is preferred. The paste may be free-standing after printing or may be deposited on any suitable substrate, for example a ceramic, a glass, a metal and the like. The paste is advantageously extrudable, shear thinning, self-supporting or any combination thereof. It is particularly advantageous that the paste is all of advantageously extrudable, shear thinning and self-supporting.

The paste preferably has a viscosity of 1,000 cP to 200,000 cP as measured when printing rates are in a range of 5-10 s⁻¹. The viscosity was evaluated using a coaxial cylinder rheometer by measurements of torque at controlled shear rates to yield viscosity profiling, shear thinning response, and yield stress. The paste forms a self-supporting structure on printing, the self-supporting structure having a yield stress of 100 Pa or greater. Yield stress is estimated as the inflection point in the graph of shear stress vs. shear rate. Shear stress is calculated as the product of Viscosity×Shear Rate (Units: Pa·s×s⁻¹=Pa).

### EXAMPLES

### Chemicals

Lead zirconate titanate (PZT) particles were purchased from APC International. Graphene oxide was purchased from Graphenea. NOA 83H, NOA 61, NOA 89H and NEA 121 uncured adhesive polymer precursors were purchased from Norland Products. N-octane (OCT), 2-ethylhexyl acrylate (EHA), polyvinyl alcohol (PVA), pentaerythritol tetra (3-mercaptopropionate) (PETMP), 4-butanediol divinyl ether (BDE) and pyrogallol were purchased from Sigma-Aldrich. 1,6-Hexanediol diacrylate (HDA) was purchased from Alfa Aesar. Sol-gel precursors, solvents and polyvinylpyrrolidone (PVP, MW=1.3 MDa) were purchased from Sigma-Aldrich with the exception of barium titanate powder (<3 μm, 99 wt %) and barium acetate (ACS reagent, 99%) which were purchased from Acros.

### Preparation of Sol-Gels

Sol-gels were prepared by adapting standard acid-catalyzed aqueous based sol-gel synthesis techniques. Unless otherwise mentioned, the sol-gels were used in the formulations as-synthesized. Sol-gels synthesis and further experimental methodology are described in International Patent Application PCT/CA2021/051173 filed Aug. 24, 2021, the entire contents of which is herein incorporated by reference.

To obtain an aqueous BTO sol-gel, 4 g barium acetate was mixed with 11.6 g glacial acetic acid. The mixture was heated to 60° C. until the barium acetate was completely dissolved. In a separate container, 1 g of titanium (IV) isopropoxide was dissolved in 1 g of isopropanol at room temperature (RT). Once the barium acetate solution was cooled to room temperature, it was then poured into titanium (IV) isopropoxide solution. The combined solutions were left to stir for 1 hour and then placed in an ice bath. During vigorous magnetic stirring, 12.76 g of MilliQ water was then poured into the cooled solution, and the solution was left to stir for 1 hour to form the aqueous BTO sol-gel.

To obtain an aqueous sol-gel containing lead, a mixture of particular titanium and zirconate alkoxides (mole ratio of Zr:Ti=52:48) was prepared along with the addition of particular solvents at room temperature. After raising the temperature of the solution to 90° C., a slight stoichiometric excess of lead acetate trihydrate was added and the mixture was allowed to cool back down to room temperature. Once at room temperature, additional solvents including a high boiling point solvent and water were added. The mixture was then left to stir overnight to obtain the aqueous sol-gel containing lead.

To obtain a lead-free aqueous sol-gel (Pb-free aqueous sol-gel), a similar process for making the sol-gel containing lead can be used, but without the addition of lead acetate. Prior to the addition of water, acetylacetone is also added at a concentration of 250 ppm (w/w) to improve the stability of the lead-free aqueous sol-gel.

### Processing of PZT Particles

PZT particles were processed prior to use to break down the large cluster of particles into individual particles. 100 g PZT particles were dispersed in 100 mL of ethanol in a beaker. The dispersion of PZT particles was stirred using a magnetic bar, and at the same time sonicated using a probe sonicator 15 with a microtip 6 mm in diameter for 25 minutes at 25 W (amplitude 15). The PZT dispersion was cooled in an ice bath during the mixing and sonication. After sonication, PZT particles were filtered and dried.

### Piezoelectric Ceramic Paste Synthesis

Carbon nanomaterials can be simply introduced to any piezoelectric ceramic paste formulation. For instance, emulsion paste formulations comprise two phases: an aqueous phase that contains acidic water (used deionized water with addition of HCl solution to adjust pH between 2 and 5), processed PZT particles and graphene oxide (GO), as well as a water-soluble polymer binder (e.g., PVA); and an organic phase that may be composed of a solvent and/or a curable polymer precursor. To prepare the emulsion, selected amounts of each component were added to a plastic jar and then mixed in a planetary centrifugal mixer (Thinky™) for 5 mins. For example, processed PZT particles, acidic water, graphene oxide, and n-octane were measured in a 100 ml plastic jar in accordance with the weight ratios for Sample 1 in Table 1 and then plenary mixed for 5 mins to achieve a stable emulsion paste. A list of tested formulations is provided in Table 1.

TABLE 1

| | | | | | | | Viscosity | |
|---|---|---|---|---|---|---|---|---|
| | | | | | | | at 5 s⁻¹ | |
| | PZT | Water | GO | PVA | Oil | Oil phase | shear rate | d₃₃ |
| # | wt % | wt % | wt % | wt % | wt % | wt % | (cP) | (pC/N) |
| 1 | 42.7 | 14.2 | 0.06 | 0 | 43.1 | 100% OCT | 43700 | |
| 2 | 44.0 | 14.6 | 0.13 | 0 | 41.3 | 100% OCT | 31800 | |
| 3 | 45.4 | 14.8 | 0.08 | 0 | 39.7 | 100% OCT | 60000 | |
| 4 | 44.3 | 14.8 | 0.16 | 0 | 40.8 | 100% OCT | 22300 | |
| 5 | 45.3 | 14.8 | 0.08 | 0.15 | 39.6 | 100% OCT | 56600 | |
| 6 | 50 | 16.5 | 0.2 | 0 | 33.3 | 100% OCT | 26100 | |
| 7 | 45.1 | 14.8 | 0.1 | 0.52 | 39.5 | 100% OCT | 84000 | |
| 8 | 42.7 | 14.3 | 0.06 | 0 | 43.0 | EHA/HDA | 25200 | |
| | | | | | | (50/50) | | |
| 9 | 43.7 | 14.1 | 0.31 | 0 | 41.8 | EHA/HDA | 65200 | |
| | | | | | | (50/50) | | |
| 10 | 43.5 | 14.1 | 0.35 | 0 | 42.1 | EHA/HDA | 45500 | |
| | | | | | | (50/50) | | |
| 11 | 42.9 | 14.3 | 0.07 | 0 | 42.8 | EHA/HDA | 21100 | |
| | | | | | | (50/50) | | |
| | | | | | | OCT | | |
| 12 | 43.5 | 14.1 | 0.36 | 0 | 42.1 | EHA/HDA | 45300 | |
| | | | | | | (50/50) | | |
| 13 | 43.4 | 14.1 | 0.34 | 0 | 42.1 | EHA/HDA | 45200 | |
| | | | | | | (50/50) | | |
| 14 | 50.6 | 16.3 | 0.40 | 0 | 32.7 | EHA/HDA | 35100 | |
| | | | | | | (50/50) | | |
| 15 | 50.8 | 16.4 | 0.16 | 0 | 32.7 | 100% OCT | 16400 | |
| 16 | 50.6 | 16.3 | 0.45 | 0 | 32.7 | PETMP | 20000 | |
| | | | | | | BDE | | |
| | | | | | | pyrogallol | | |
| 17 | 54.6 | 13.9 | 0.15 | 0 | 31.3 | NOA 83H | N/A | |
| 18 | 55.0 | 13.8 | 0.18 | 0 | 31.0 | NOA 61 | N/A | |
| 19 | 50.9 | 16.3 | 0 | 0 | 32.8 | NOA 89H | 8700 | 9.3 ± 0.62 |
| 20 | 50.8 | 16.4 | 0.15 | 0 | 32.7 | NOA 89H | 15800 | 8.2 ± 0.62 |
| 21 | 50.7 | 16.3 | 0.33 | 0 | 32.7 | NOA 89H | 20700 | 9.0 ± 1.50 |
| 22 | 50.5 | 16.3 | 0.67 | 0 | 32.5 | NOA 89H | 26500 | 16.0 ± 1.85 |
| 23 | 50.3 | 16.3 | 1.01 | 0 | 32.4 | NOA 89H | N/A | 9.6 ± 0.65 |
| 24 | 81.1 | 7.6 | 0.32 | 0 | 10.7 | NEA 121 | N/A | 26.5 |
| 25 | 81.1 | 7.5 | 0.16 | 0 | 10.9 | NEA 121 | N/A | 39.5 |
| 26 | 81.1 | 7.5 | 0.12 | 0 | 10.7 | NEA 121 | N/A | 21.0 |
| 27 | 81.4 | 7.5 | 0.08 | 0 | 10.7 | NEA 121 | N/A | 18.0 |
| 28 | 81.4 | 7.5 | 0 | 0 | 10.7 | NEA 121 | N/A | 17.0 |

### Printing and Curing

The prepared pastes were placed into 30 mL syringe tubes and the piston was pushed the paste to the end to remove air inside. A tapered nozzle with inner diameter of 1.19 mm was attached to the syringe before being installed in a 3D printer. A commercially available 3D printer (Hyrel™ System 30M, Atlanta, GA) was used to 3D print the samples using Direct Ink Writing. The ceramic pastes were deposited onto a thin film Kapton™ sheet on top of the print bed to build a 3D structure in dimensions of 15×15×3 mm³. Samples were printed with a speed of 10 mm/s and a layer height of 0.95 mm.

After printing, samples were dried at room temperature for 12 hours to prevent crack formation due to water evaporation. The samples, then, were cured at 80° C. for 4 hours. The thin Kapton™ film helps 3D printed samples peel off easily from the bed.

### Poling and d₃₃ Measurements

The samples were placed inside an oil bath and poled under 10 kV at 120° C. for 1 h using a high-voltage power supply (ES60, 10 W negative, Gamma High Voltage Research, Inc.). The samples were then cooled down to room temperature before removing the electric field. Piezoelectric charge coefficient (d₃₃) was measured using APC make d₃₃ meter model S5865.

### Viscosity Measurements and SEM Imaging

The viscosity of the emulsion paste was measured using a Brookfield RV-DV-III Ultra Rheometer. The printed and cured samples were imaged on a Hitachi SU3500 or a Hitachi S-4700 scanning electron microscope (SEM) to observe the morphology.

### Results

The effect of graphene oxide (GO) concentration in PZT emulsion pastes and a PZT sol-gel paste was examined.

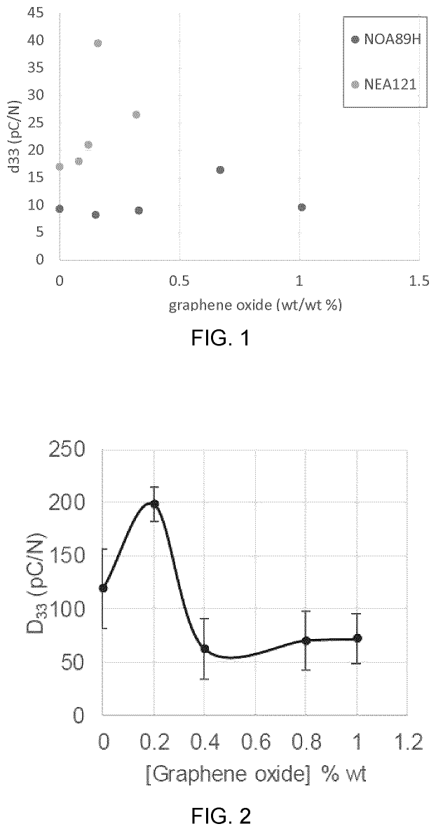

As graphene oxide (GO) concentration increases in the emulsion pastes, the viscosity of the paste increases (see Samples 19 to 22 in Table 1) indicating that by selecting an appropriate concentration of the carbon nanomaterial, an appropriate viscosity can be tuned in order to achieve a printable paste. The effect of GO on piezoelectric performance in PZT emulsion pastes (based on NOA 89H and NEA 121 as curable polymer precursors) is shown in FIG. 1. Adding GO at an appropriate concentration increases the d₃₃ values. In each system, there is a different optimum GO concentration, and beyond the optimum GO concertation, an increase in d₃₃ value may not be realized. The optimum GO concentration may be related to the viscosity of the paste. In FIG. 1, NEA 121 samples (50 vol % PZT) have higher viscosity compared to NOA 89H samples (17 vol % PZT), and a lower optimum GO concentration is observed.

A similar observation of the effect of GO concentration on of d₃₃ values (FIG. 2) was made for an annealed lead zirconate titanate (PZT) sol-gel paste containing 80 wt % PZT with PVP polymer binder.

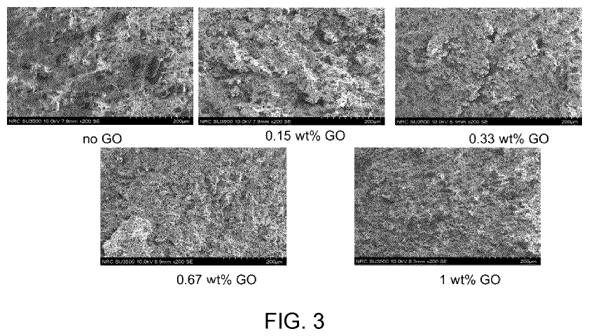

In addition, SEM images of the PZT emulsion paste with various amount of GO (FIG. 3) indicate that the addition of GO particles do not interfere with the morphology of the PZT emulsion paste. And no change in morphology was observed with an increase of GO concentration.

The novel features will become apparent to those of skill in the art upon examination of the description. It should be understood, however, that the scope of the claims should not be limited by the embodiments, but should be given the broadest interpretation consistent with the wording of the claims and the specification as a whole.

1. An extrudable composition comprising piezoelectric ceramic particles and carbon nanomaterial particles suspended in a carrier medium.

2. The composition of claim 1, wherein the carbon nanomaterial particles comprise graphite, graphene, graphene oxide (GO), reduced graphene oxide (r-GO), carbon nanotubes, fullerenes, carbon nanofibers or any mixture thereof.

3. The composition of claim 1, wherein the carbon nanomaterial particles comprise graphene oxide (GO).

4. The composition of claim 1, wherein the carbon nanomaterial particles are present in the paste in an amount in a range of 0.01-2 wt % based on total weight of the composition.

5. The composition of claim 1, wherein the carbon nanomaterial particles are present in the paste in an amount in a range of 0.05-1 wt % based on total weight of the composition.

6. The composition of claim 1, wherein the ceramic particles comprise lead zirconate titanate (PZT) particles.

7. The composition of claim 1, wherein the ceramic particles are present in the paste in an amount of 90 wt % or less, based on total weight of the composition.

8. The composition of claim 1 having a viscosity in a range of 1,000-200,000 cP, as measured when printing shear rates are in a range of 5-10 s⁻¹.

9. The composition of claim 1, wherein the carrier medium comprises one or more of a sol-gel, an organic polymer binder, an organic solvent, acidic water or a curable polymer precursor.

10. The composition of claim 1, having a form factor selected from the group consisting of a composite filament, a composite pellet, a composite powder, and a composite paste.

11. The composition of claim 10, wherein the form factor is a composite paste.

12. A piezoelectric ceramic material produced by curing the composition as defined in claim 1.
